(19) United States
(12) Patent Application Publication
(10) Pub. No.: US 2005/0110161 A1
(43) Pub. Date: May 26, 2005

(54) Method for mounting semiconductor chip and semiconductor chip-mounted board

(76) Inventors: Hiroyuki Naito, Toyonaka-shi (JP); Satoshi Shida, Hirakata-shi (JP); Hiroshi Haji, Chikushino-shi (JP); Makoto Morikawa, Ikoma-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/958,246

(22) Filed: Oct. 6, 2004

(30) Foreign Application Priority Data
Oct. 7, 2003 (JP) 2003-347977

(51) Int. Cl. H01L 23/48

(52) U.S. Cl. 257/778

(57) ABSTRACT

By arranging bonding members formed of a gold nanopaste between chip-electrodes and board-electrodes, making the chip-electrodes are brought in contact with the respective board-electrodes via the bonding members and applying ultrasonic vibrations to the bonding members in the contact state, the bonding members are bonded to the board-electrodes and the chip-electrodes.

### BACKGROUND OF THE INVENTION

The present invention relates to a semiconductor chip mounting method for producing a semiconductor chip-mounted board by bonding board-electrodes of a board to chip-electrodes of a semiconductor chip to mount the semiconductor chip on the board, and relates to the semiconductor chip-mounted board.

Conventionally, an LED (LED chip), which is one example of the semiconductor chip, has been used for a fluorescent lamp or the like by utilizing its light-emitting function. However, the LED, which can emit light with a voltage applied thereto, has a problem that heat is generated accompanying the light emission and the luminous efficiency of the LED is reduced by the generation of heat, causing a reduction in the luminous intensity. In order to solve the problem, various devices have conventionally been invented to let the heat generated from the LED efficiently escape.

For example, as one of the devices, a technique for letting heat escape to the board via the bumps of LED that are bonded to the board via the bumps. According to the technique, in order to increase the contact area (heat transfer area) of the bumps, the bumps are formed as plating bumps by a plating process suitable for the formation of bumps of a comparatively large size.

The conventional method for mounting an LED on the board as described above will be described below (see, for example, Japanese unexamined patent publication No. 2000-68327) with reference to the drawings.

FIGS. 10A and 10B show schematic explanatory views schematically showing an LED mounting method. As shown in FIG. 10A, the LED 501 is provided with pads 502 of one example of a plurality of chip-electrodes formed of aluminum (Al) on the lower surface side. Moreover, a board 503 is provided with a plurality of board-electrodes 504, which are formed in accordance with the arrangement of the pads 502 of the LED 501 on the upper surface side in the figure. Further, a bump 505 (hereinafter referred to as a bump 505) of one example of the protruding electrodes formed of gold (Au) by the plating method is formed on each of the board-electrodes 504 of the board 503.

As shown in FIG. 10A, by sucking and holding the illustrated upper surface of the LED 501 by means of moving the suction nozzle 510 in a horizontal direction relatively to the board 503, the pads 502 of the LED 501 are aligned in a position with the bumps 505 of the board 503. Subsequently, by moving down the suction nozzle 510, the bumps 505 are brought in contact with the respective pads 502.

Next, as shown in FIG. 10B, ultrasonic vibrations are applied from the suction nozzle 510 to the LED 501 with the contact state maintained. As a result, metal bonding is achieved at the contact portions of the bumps 505 and the pads 502, so that the LED 501 is mounted on the board 503.

The bumps 505 are possibly formed on the pads 502 of the LED 501 or formed on both the board-electrodes 504 and the pads 502 besides the case where the bumps are formed on the board-electrodes 504 of the board 503.

A general method for forming the gold bumps 505 by the plating method used by the conventional mounting method will be described herein with reference to the flow chart shown in FIG. 13. Referring to the flow chart of FIG. 13, the case where the bumps 505 are formed on the semiconductor chip side will be described.

First, in step S1 of the flow chart of FIG. 13, a wafer, which becomes a semiconductor chip (e.g., LED), is received. Subsequently, in step S2, a plating common electrode film is formed by, for example, UBM sputtering on the wafer surface on which the chip-electrodes are formed. Subsequently, in step S3, a resist film for plating is formed on the UBM surface with patterning of a plating bump form.

Subsequently, in step S4, gold bumps are formed by electrolytic plating by using the resist film for plating. Subsequently, in step S5, the resist film for plating existing around the formed gold bump is peeled off to remove the resist film for plating. Subsequently, in step S6, the UBM is etched to reduce the thickness of the UBM. Finally, in step S7, the formed gold bumps are inspected, completing the formation of the gold bumps.

### DISCLOSURE OF THE INVENTION

However, according to the semiconductor chip mounting method, as described above, the bumps 505 formed on the LED 501 by the plating method have a large size, and in this accordance, the contact area of each bump 505 and each board-electrode 504 when put in contact is also increased. Accordingly, there is the possible occurrence of a case where sufficient vibrations for bonding cannot be applied by ultrasonic vibrations or a case where a time during which the ultrasonic vibrations are applied for bonding becomes long. In the above cases, there is a problem that it becomes difficult to reliably bond the LED 501 to the board 503. Such a problem similarly occurs not only when the bumps 501 are formed on the LED 501 side but also when the bumps 505 are formed on the board 503 side as shown in FIGS. 10A and 10B.

The occurrence of defective bonding will be described in concrete with reference to the schematic explanatory views of FIGS. 11A, 11B and 11C. In the schematic explanatory views of FIGS. 11A, 11B and FIG. 11C, the bumps 505 are formed on the LED 501 side.

If the metal bonding starts between the bumps 505 and the respective board-electrodes 504 by applying ultrasonic vibrations and the metal bonding progresses as shown in FIG. 11A, then the bonding between the bumps 505 and the pads 502 of the LED 501 progresses by the application of ultrasonic vibrations as shown in FIG. 11B. If the bonding between the bumps 505 formed of gold and the pads 502 formed of aluminum progresses, then diffusion between gold and aluminum progresses to form an alloy layer 505a of aluminum and gold in the upper portions in the figure of the bumps 505 as shown in FIG. 11C, and the alloy layer 505a increases with further application of the ultrasonic vibrations. This alloy layer 505a has a characteristic that it is hard and fragile in comparison with the bumps formed of gold, and therefore, stress concentration might occur in the main body of the LED 501 due to the application of the ultrasonic vibrations, possibly causing cracks in the LED 501. Particularly, such a problem becomes remarkable with an increase in the duration of bonding when the bumps 501 of a large size are used.

Moreover, since the bumps 505 are formed on the LED 501 by the plating method, it is often the case where the formation heights of the bumps 505 are minutely varied as shown in FIG. 12A. In the above case, as shown in FIG. 12B, the bump 505 of the higher formation height comes in contact with the board-electrode 504 of the board 503 ahead of the bump 505 of the lower formation height, and consequently the bonding of the former bump 505 is completed ahead of the latter bump 505. As shown in FIG. 12C, even after the completion of the bonding of one bump 505, if the application of the ultrasonic vibrations is continued for the bonding of the other bumps 505, then stress concentration occurs in the one bump 505, possibly accompanying the generation of cracks.

Moreover, it can be considered to preliminarily carry out a process for uniforming the formation height of the bumps in order to uniform the formation height of the bumps 505. However, there is a problem that the bumps 505 are hard since they are formed by the plating method, and it is required to carry out an abrasion process as the above process, needing much processing time and labor for the abrasion process.

Moreover, the plating method adopted for forming large-size bumps 505 on the pads 502 of the LED 501 requires many processing steps as described above, and much time and labor are needed. For example, a time of about three days are sometimes needed to carry out the plating method. Moreover, it is necessity to carry out an inspection process of the bumps 505 formed by the plating method, and this needs more time and labor.

On the other hand, it can also be considered to form solder bumps on the pads of the LED without carrying out the bonding by the application of ultrasonic vibrations that accompany the various problems and to carry out the bonding of the LED to the board by reflow of the solder bumps. However, according to the reflow mounting method using the solder bumps, it is necessary to heat the solder bumps to a temperature of, for example, not lower than 238° C. in order to melt the solder bumps. In contrast to this, due to the fact that the allowable temperature of the LED is not higher than about 200° C., the reflow mounting method cannot be applied to the mounting of the LED. There is a further problem that the light-emitting surface of the LED is disadvantageously contaminated by gas elements and so on in the reflow atmosphere and the light-emitting function is degraded.

Moreover, even when the semiconductor chip is not the LED and the allowable temperature is not lower than 238° C., a flux feed process and a cleaning process are needed in accordance with the use of solder, and time and labor are needed for the execution of the reflow mounting method. Moreover, the use of solder is contradictory to the lead-free arrangement to cope with the recent environmental problems.

Accordingly, the object of the present invention is to solve the aforementioned problems and provide a semiconductor chip mounting method capable of carrying out reliable efficient bonding while reducing the occurrence of defective bonding caused by the application of ultrasonic vibrations in mounting a semiconductor chip on a board by bonding chip-electrodes of the semiconductor chip to board-electrodes of the board by applying the ultrasonic vibrations, and a semiconductor chip-mounted board.

In accomplishing the object, the present invention is constructed as follows.

According to a first aspect of the present invention, there is provided a semiconductor chip mounting method for mounting a semiconductor chip that has a chip-electrode bondable to a board-electrode of a board by bonding the chip-electrode to the board-electrode, the method comprising:
arranging a bonding member formed of a conductive material in paste form between the chip-electrode and the board-electrode and bringing the chip-electrode in contact with the board-electrode by interposing the bonding member; and
applying ultrasonic vibrations to the bonding member and either the chip-electrode or the board-electrode in the contact state, thereby the bonding member is bonded to the board-electrode and the chip-electrode.

According to a second aspect of the present invention, there is provided a semiconductor chip mounting method for mounting a semiconductor chip that has a plurality of chip-electrodes bondable to board-electrodes of a board by bonding the chip-electrodes to the board-electrodes, the method comprising:
arranging bonding members formed of a conductive material in paste form between the chip-electrodes and the board-electrodes and bringing the chip-electrodes in contact with the respective board-electrodes by interposing the bonding members; and
applying ultrasonic vibrations to the bonding members and either the chip-electrodes or the board-electrodes in the contact state, thereby the bonding members are bonded to the board-electrodes and the chip-electrodes.

According to a third aspect of the present invention, there is provided a semiconductor chip mounting method as defined in the second aspect, wherein
the conductive material in the paste form is fed by coating or printing to the board-electrodes or the chip-electrodes,
the bonding members are formed by imparting energy to the fed conductive material in the paste form, and
then, the chip-electrodes are brought in contact with the respective board-electrodes with interposition of the bonding members.

According to a fourth aspect of the present invention, there is provided a semiconductor chip mounting method as defined in the third aspect, wherein the bonding members are formed by stabilizing shapes thereof formed of the conductive material in the paste form with imparting the energy thereto, after the conductive material in the paste form is fed.

According to a fifth aspect of the present invention, there is provided a semiconductor chip mounting method as defined in the third aspect, wherein the conductive material in the paste form is a gold nanopaste, and the bonding material is a metal film produced by imparting the energy to the gold nanopaste.

According to a sixth aspect of the present invention, there is provided a semiconductor chip mounting method as defined in the third aspect, wherein the chip-electrodes are brought in contact with the respective board-electrodes with interposition of the bonding members by deforming the bonding members with pressurizing the chip-electrodes against the board-electrodes with interposition of the bonding members.

According to a seventh aspect of the present invention, there is provided a semiconductor chip mounting method as defined in the third aspect, wherein a plurality of the bonding members are formed on the individual board-electrodes or the individual chip-electrodes.

According to an eighth aspect of the present invention, there is provided a semiconductor chip mounting method as defined in the third aspect, wherein the ultrasonic vibrations are applied to the bonding members through the semiconductor chip by a component holding member in a state in which a surface to be held opposite from a surface of the semiconductor chip on which the chip-electrodes are formed is held by a holding surface of the component holding member.

According to a ninth aspect of the present invention, there is provided a semiconductor chip mounting method as defined in the third aspect, wherein the semiconductor chip has a P-type electrode and an N-type electrode, whose thickness dimensions are different from each other, as the chip-electrodes, and
the bonding members are formed so that the thickness dimensions of the bonding members are varied in accordance with a difference in a distance dimension between the chip-electrodes and the board-electrodes depending on the difference in the thickness dimension between the P-type electrode and the N-type electrode.

According to a tenth aspect of the present invention, there is provided a semiconductor chip mounting method as defined in the second aspect, wherein
the semiconductor chip has a plurality of protruding electrodes formed on the chip-electrodes,
the bonding members are formed by feeding the conductive material in the paste form to the protruding electrodes or the board-electrodes and imparting energy to the conductive material in the paste form, and
the chip-electrodes are brought in contact with the respective board-electrodes by interposition of the bonding members and the protruding electrodes.

According to an eleventh aspect of the present invention, there is provided a semiconductor chip mounting method as defined in the tenth aspect, wherein the protruding electrodes are formed of a conductive material by a plating method.

According to a twelfth aspect of the present invention, there is provided a semiconductor chip mounting method as defined in the tenth aspect, wherein
the semiconductor chip has a P-pole electrode and an N-pole electrode, whose thickness dimensions are different from each other, as the chip-electrodes, and
the bonding members are fed so that thickness dimensions of the bonding members are varied in accordance with a difference in a distance dimension between tips of the protruding electrodes and the board-electrodes caused by a difference in a tip height position of the protruding electrodes based on the difference in the thickness dimension of the chip-electrodes.

According to a thirteenth aspect of the present invention, there is provided a semiconductor chip mounting method as defined in the second aspect, wherein
the board has a plurality of protruding electrodes formed on the board-electrodes,
the bonding members are formed by feeding the conductive material in the paste form to the protruding electrodes or the chip-electrodes and imparting energy to the conductive material in the paste form, and
the chip-electrodes are brought in contact with the respective board-electrodes with interposition of the bonding members and the protruding electrodes.

According to a fourteenth aspect of the present invention, there is provided a semiconductor chip mounting method as defined in the thirteenth aspect, wherein
the semiconductor chip has a P-pole electrode and an N-pole electrode, whose thickness dimensions are different from each other, as the chip-electrodes,
the bonding members are fed so that thickness dimensions of the bonding members are varied in accordance with a difference in a distance dimension between the chip-electrodes and the tips of the protruding electrodes caused by a difference in a thickness dimension of the chip-electrodes.

According to a fifteenth aspect of the present invention, there is provided a semiconductor chip mounting method as defined in the third aspect, wherein the board-electrodes of the board are subjected to a plasma cleaning process before the contact between the chip-electrodes of the semiconductor chip and the board-electrodes of the board with interposition of the bonding members.

According to a sixteenth aspect of the present invention, there is provided a semiconductor chip mounting method as defined in the third aspect, wherein, after the bonding between the chip-electrodes of the semiconductor chip and the board-electrodes of the board with interposition of the bonding members, peripheries of the bonded portions are subjected to a sealing process with an insulating material.

According to a seventeenth aspect of the present invention, there is provided a semiconductor chip mounting method as defined in the third aspect, wherein the semiconductor chip is an LED chip, and the bonding members have a function to transfer heat generated by voltage application to the LED chip toward the board side.

According to an eighteenth aspect of the present invention, there is provided a semiconductor chip-mounted board comprising:
a board having a plurality of board-electrodes;
a semiconductor chip having a plurality of chip-electrodes electrically bondable to the board-electrodes; and
a plurality of bonding members that are arranged between the board-electrodes and the chip-electrodes and formed into a metal film by imparting energy to a gold nanopaste,
wherein the semiconductor chip being mounted on the board by bonding the chip-electrodes to the respective board-electrodes with interposition of the bonding members by adhesion of the bonding members to the board-electrodes or the chip-electrodes.

According to a nineteenth aspect of the present invention, there is provided a semiconductor chip mounting method for mounting a semiconductor chip that has a plurality of chip-electrodes on a board that has a plurality of board-electrodes, the method comprising:

arranging bonding members formed by imparting energy to a conductive material in paste form between the chip-electrodes and the board-electrodes; pressurizing the chip-electrodes against the respective board-electrodes with interposition of the bonding members between the chip-electrodes and the board-electrodes; and deforming the bonding members, thereby bringing the chip-electrodes in contact with the respective board-electrodes with interposition of the bonding members.

According to the first and second aspects of the present invention, the chip-electrodes of the semiconductor chip and the board-electrodes of the board have a high hardness of, for example, about 70 to 90 HV. Therefore, a sufficient contact area cannot be secured by only applying ultrasonic vibrations in the state in which both the electrodes are brought in contact with each other, and it is difficult to achieve sufficient metal bonding. In contrast to this, by arranging the bonding members formed of a conductive material of a soft material in paste form between the chip-electrodes and the board-electrodes, interposing the bonding members having the hardness sufficiently lower than the hardness of the chip-electrodes and the board-electrodes and applying the ultrasonic vibrations while bringing the chip-electrodes in contact with the respective board-electrodes, sufficient metal bonding can be achieved.

That is, by pressurizing the bonding members having the characteristic of softness in comparison with those of the chip-electrodes and the board-electrodes between the chip-electrodes and the board-electrodes during the contact to minutely deform the bonding members, the chip-electrodes and the respective board-electrodes can be reliably brought into contact with interposition of the bonding members. Moreover, a sufficient bonding area (contact area) is secured in the contact portions of the chip-electrodes or the board-electrodes and the bonding members during the contact. By applying the ultrasonic vibrations in the above state, metal bonding can reliably be achieved with the sufficient bonding area and a sufficient bonding strength, so that the stable bonding can be achieved.

According to the third aspect or the fourth aspect of the present invention, with regard to the arrangement of the bonding members, the bonding members can be formed by feeding the conductive material in the paste form to the chip-electrodes or the board-electrodes by coating or printing means and thereafter imparting energy to the fed conductive material in the paste form. That is, by virtue of the conductive material in the paste form having the characteristic of softness, the coating or printing means can be used. Furthermore, by imparting the energy of, for example, thermal energy, ultrasonic energy or electron beam to the conductive material in the soft state, the shape of the conductive material in the paste form can be stabilized. By virtue of the stabilization effected, the bonding members can easily be deformed by receiving an external force applied, whereas the shape can be maintained in the stabilized state in the state in which no external force is applied. Therefore, by using the coating or printing means, the feed rate of the conductive material can be controlled with high accuracy, and the formation of the bonding members can be formed with high accuracy. In addition, by maintaining the shape formed by feeding the conductive material in the paste having the characteristic of softness in the stabilized state, more reliable contact and bonding can be achieved.

According to another aspect of the present invention, the conductive material in the paste form is the gold nanopaste, by which the bonding members appropriate in terms of conductive property, thermal conductivity, oxidation resistance and so on can be formed. Particularly, by virtue of the use of the gold nanopaste, a metal film can be formed by imparting energy to the gold nanopaste, and more stable and reliable bonding can be achieved.

Moreover, the chip-electrodes are brought in contact with the respective board-electrodes with interposition of the bonding members by pressurizing the chip-electrodes against the respective board-electrodes with interposition of the bonding members to deform the bonding members. With this arrangement, even when there are variations in the formation thickness of the chip-electrodes and in the formation thickness of the board-electrodes, the variations can be absorbed by deforming the bonding members, and reliable bonding can be achieved.

Moreover, the ratio of the formation width with respect to the formation height of the bonding member can be reduced by forming a plurality of the bonding members on each individual board-electrode or chip-electrode, so that the bonding members are allowed to have a shape that is more easily deformed by the application of ultrasonic vibrations. Therefore, the time during which the ultrasonic vibrations are applied for the bonding can be shortened, and more efficient and stable bonding can be achieved by the application of ultrasonic vibrations.

Moreover, by forming the bonding members so that the thickness dimensions are varied by regulating the feed rate of the conductive material of, for example, gold nanopaste according to the difference in the distance dimension between the tips of the chip-electrodes of the semiconductor chip having the feature that the formation heights of the P-pole pad and the N-pole pad of the chip-electrodes differ from each other and the board-electrodes of the board, reliable and stable mounting can be carried out coping with the difference in the formation thickness (height) between the P-pole pad and the N-pole pad. That is, even when the formation heights of the chip-electrodes are varied as described above, the mounting of the semiconductor chip can be achieved by adjusting the variation with the bonding members while maintaining the levelness between the semiconductor chip and the board. The above effect can be effectively obtained particularly when the semiconductor chip is an LED chip that has the aforementioned features.

Moreover, an effect similar to the above effect can be obtained-even when protruding electrodes are formed on the chip-electrodes of the semiconductor chip or the board-electrodes of the board.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1 is a schematic plan view showing the structure of an LED chip used by a mounting method according to a first embodiment of the present invention;

FIG. 2 is a schematic sectional view showing the structure of the LED chip of FIG. 1;

FIG. 3A is a schematic sectional view of the LED chip of FIG. 1; FIG. 3B is a schematic sectional view of a board on which the LED chip will be mounted;

FIGS. 4A through 4F are schematic explanatory views showing the procedure of an LED chip mounting method according to the first embodiment of the present invention, where FIG. 4A is a schematic sectional view of the LED chip on which bumps are formed, FIG. 4B is a schematic sectional view of the board on which bonding electrodes are formed, FIG. 4C is a schematic enlarged sectional view of the bonding electrode formed of a gold nanopaste, FIG. 4D is a view of a state in which the LED chip and the board are aligned with each other in position, FIG. 4E is a view of a state in which ultrasonic vibrations are applied to the LED chip and the board put in a mutual contact state, and FIG. 4F is a view of a state in which a sealing process is carried out;

FIGS. 5A through 5E are schematic explanatory views showing the procedure of an LED chip mounting method according to a second embodiment of the present invention, where FIG. 5A is a schematic sectional view of the LED chip on which bumps are formed, FIG. 5B is a schematic sectional view of a board on which bonding electrodes are formed, FIG. 5C is a view of a state in which the LED chip and the board are aligned with each other in position, FIG. 5D is a view of a state in which the ultrasonic vibrations are applied to the LED chip and the board put in a mutual contact state, and FIG. 5E is a view of a state in which the mounting is completed;

FIG. 6 is a schematic enlarged sectional view of a bonding electrode employed by an LED chip mounting method according to a modification example of the first embodiment;

FIG. 7 is a schematic sectional view showing a LED chip mounting method according to the modification example of the first embodiment, in which the bonding electrodes are formed on the bumps of the LED chip;

FIGS. 8A, 8B and 8C are schematic explanatory views showing the procedure of an LED chip mounting method according to a third embodiment of the present invention, where FIG. 8A is view of a state in which the LED chip and a board with no bump formed are aligned with each other in position, FIG. 8B is a view of a state in which the ultrasonic vibrations are applied to the LED chip and the board put in a mutual contact state, and FIG. 8C is a view of a state in which a sealing process is carried out;

FIG. 9 is a schematic explanatory view showing the relation between a bonding load and a friction coefficient according to a conventional semiconductor chip mounting method by the application of ultrasonic vibrations;

FIGS. 10A and 10B are schematic explanatory views showing the conventional semiconductor chip mounting method, where FIG. 10A is a view of a state in which a semiconductor chip and a board are aligned with each other in position, and FIG. 10B is a view of a state in which ultrasonic vibrations are applied to the semiconductor chip and the board put in a mutual contact state;

FIGS. 11A, 11B and 11C are schematic explanatory views further showing the conventional semiconductor chip mounting method, where FIG. 11A is a view of a state in which the ultrasonic vibrations start being applied, FIG. 11B is a view of a state in which diffusion between the chip-electrodes and the bumps progresses, and FIG. 11C is a view of a state in which cracks are generated in an alloy layer;

FIGS. 12A, 12B and 12C are schematic explanatory views showing another conventional semiconductor chip mounting method, where FIG. 12A is a view of a state in which a variation in height between the bumps formed on the semiconductor chip occurs, FIG. 12B is a view of a state in which the ultrasonic vibrations are applied to the bumps with only one bump brought put in contact, and FIG. 12C is a view of a state in which the bonding to the other bump is carried out despite that the bonding of the one bump has been completed;

FIG. 13 is a flow chart showing a gold bump forming process of the conventional semiconductor chip mounting method by the plating method;

FIG. 14 is an enlarged sectional view of a state in which an LED chip is mounted on a board according to a working example of the present invention;

FIGS. 15A and 15B are schematic explanatory views showing the procedure of an LED chip mounting method according to a modification example of the first embodiment, where FIG. 15A is a view of a state in which the positional alignment of the LED chip with a board is achieved, and FIG. 15B is a view of a state in which the ultrasonic vibrations are applied to the LED chip and the board put in a mutual contact state;

FIGS. 16A and 16B are schematic explanatory views showing the procedure of an LED chip mounting method according to a modification example of the first embodiments where FIG. 16A is a view of a state in which bumps are formed on both the LED chip and the board and the positional alignment of the chip LED with the board is achieved, and FIG. 16B is a view of a state in which the ultrasonic vibrations are applied to the LED chip and the board put in a mutual contact state; and

FIGS. 17A, 17B, 17C and 17D are schematic sectional views of the mechanism of a process for stabilizing the gold nanopaste, where FIG. 17A is a view showing a dispersion state at normal temperature, FIG. 17B is a view showing a state in which energy starts being imparted, FIG. 17C is a view showing a state in which gold nanoparticles start being fused, and FIG. 17D is a view showing a state in which the fusion is completed.

### DETAILED DESCRIPTION OF THE PREFERRED EMBODIMENTS

Before the description of the present invention proceeds, it is to be noted that like parts are designated by like reference numerals throughout the accompanying drawings.

Hereinbelow, embodiments of the present invention are described in detail with reference to the accompanying drawings.

### First Embodiment

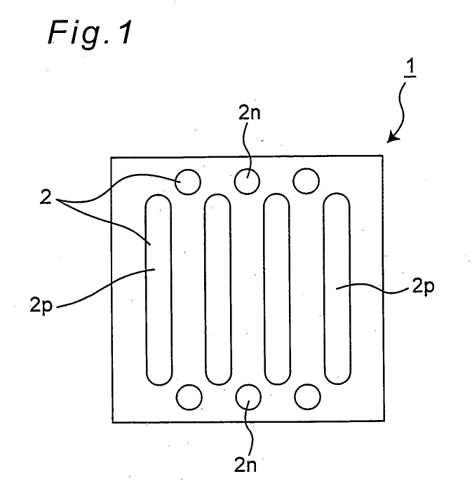

In connection with a semiconductor chip mounting method according to the first embodiment of the present invention, FIG. 1 shows a schematic explanatory view illustrating the planar structure of an LED chip (or an LED device) to be mounted on a board of one example of the semiconductor chip.

As shown in FIG. 1, the LED (Light Emitting Diode) chip 1 has an approximate square shape, and a plurality of pads 2 of one example of the chip-electrodes are formed on the bonding side surface of the board. The pads 2 are formed separated into two kinds of P-pole pads (one example of the P-type electrode) 2p formed into an elliptic shape and N-pole pads (one example of the N-type electrode) 2n formed into an approximate circle shape according to the characteristics of the LED chip 1. For example, each of the P-pole pads 2p is formed in a size of about 0.6 mm×0.1 mm, and each of the N-pole pads 2n is formed in a size of a diameter of about 0.1 mm.

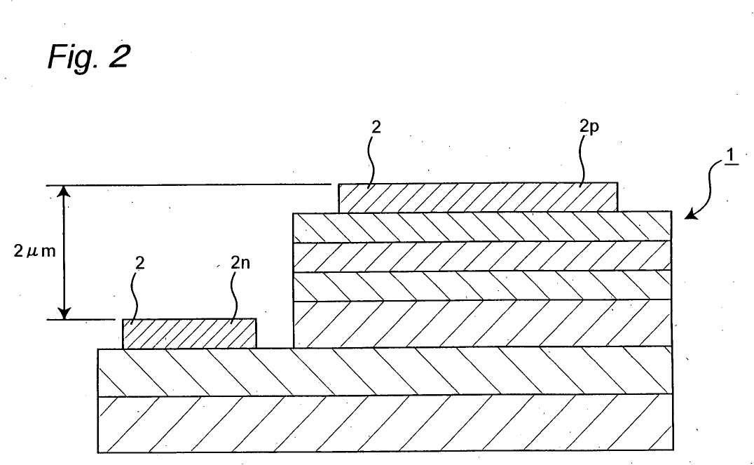

Moreover, FIG. 2 shows a schematic sectional view of the LED chip 1. As shown in FIG. 2, the LED chip 1 has a multi-layered structure, and the pads 2 are formed so that the formation heights (formation thicknesses) of the P-pole pad 2p and the N-pole pad 2n on the pad formation surface on which the pads 2 are provided are different. The difference in the formation height of the pads 2 is attributed to the characteristics of the LED chip 1. For example, in a state in which the pad formation surface of the LED chip 1 serves as the upper surface, the P-pole pad 2p is located in a position higher than the N-pole pad 2n, and the difference in the formation height between them is about 2 μm.

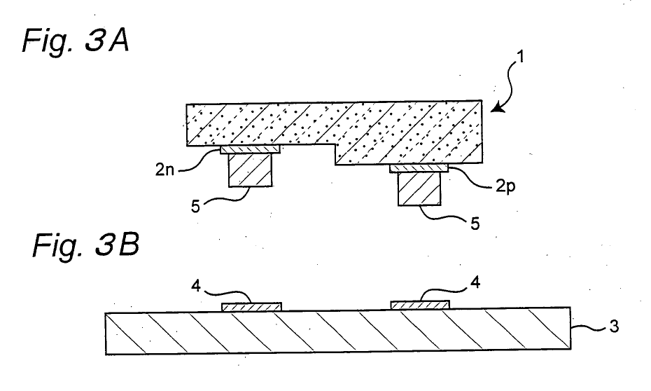

Further, FIG. 3A shows a schematic sectional view of the LED chip 1, and FIG. 3B shows a schematic sectional view of a board 3 on which the LED chip 1 shown in FIG. 3A is to be mounted. As shown in FIG. 3A, bumps 5 of one example of the protruding electrode are formed on the pads 2 of the LED chip 1. The bumps 5 are possible to be formed of, for example, gold (Au) of one example of the conductive material by the plating method. Moreover, as shown in FIG. 3B, a plurality of board-electrodes 4 are formed on the surface of the approximately flat-plate-shaped board 3, on which the LED chip 1 is to be mounted, or the upper surface in the figure. The arrangement of the board-electrodes 4 on the surface of the board 3 is formed so as to correspond to (coincide with) the arrangement of the pads 2 of the LED chip 1. With the pads 2 and the board-electrodes 4 being thus arranged and formed, the pads 2 of the LED chip 1 can be bonded to the respective board-electrodes 4 of the board 3 via the bumps 5. It is to be noted that the board of the present invention includes a circuit board such as a silicon (Si) wafer, a resin board, a paper phenol board, a ceramic board, a glass epoxy board or a film board, a circuit board such as a single board or a multilayer board and an object on which a circuit is formed, such as a component, a casing or a frame.

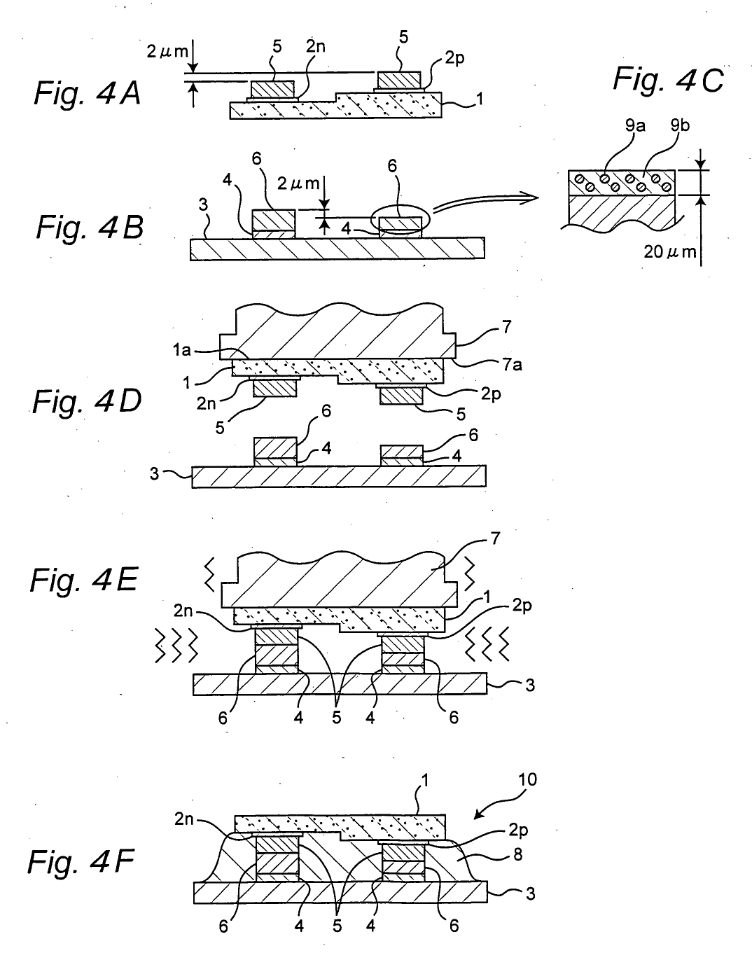

However, as described above, since the formation heights of the P-pole pads 2p and the N-pole pads 2n are different on the LED chip 1, the tip height positions of the bumps 5 formed by the plating method or the like are also different according to the difference in the formation height. A method for mounting the LED chip 1 on the board 3 without the influence of the difference even when the formation heights of the pads 2 are different will be described below with reference to the explanatory views using the schematic sectional views of the LED chip 1 and the board 3 shown in FIGS. 4A, 4B, 4C, 4D, 4E and 4F.

First of all, as shown in FIG. 4A, bumps 5 (gold bumps) are formed of gold by, for example the plating method on the upper surfaces of the P-pole pad 2p and the N-pole pad 2n of the LED chip 1. Although the P-pole pad 2p and the N-pole pad 2n have a formation height difference of, for example, about 2 μm, it is difficult to vary the formation heights of the individual bumps 5 when the bumps 5 are formed by the plating method. Therefore, the bumps 5 are formed to have approximately equal formation heights. Therefore, as shown in FIG. 4A, the illustrated tip height position of the bump 5 formed on the P-pole pad 2p and the illustrated tip height position of the bump 5 formed on the N-pole pad 2n differ from each other, and the difference becomes, for example, about 2 μm.

Next, a gold nanopaste (one example of the metal nanopaste) of one example of the conductive material in the paste form, is fed onto the illustrated upper surfaces of the board-electrodes 4 of the board 3 on which the LED chip 1 is mounted by using coating or printing means concurrently with the bump formation process, forming a plurality of bonding electrodes 6 of one example of the bonding member. It may be a case where the board-electrodes 4 of the board 3 are subjected to a plasma cleaning process before the formation of the bonding electrodes 6. The above case has an advantage that the surfaces of the board-electrodes 4 can be put in a clean state, and the adhesion between the surfaces of the board-electrodes 4 and the gold nanopaste fed to the surfaces can be made satisfactory.

Here, as shown in FIG. 4C, the “gold nanopaste” is a conductive material in paste form constructed of numbers of gold nanoparticles (conductive particles) 9a of superfine gold particles formed of gold and additive elements 9b (including, for example, an adhesive element and various kinds of additives, not always limited to a case where the individual elements have a conductive property). Moreover, the gold nanopaste is a soft material that has a plasticity characteristic capable of easily changing its shape (form) by receiving an external force applied.

However, the gold nanopaste has a characteristic that it is very soft as it is and possesses hardness and viscosity such that its shape cannot be stably maintained or its shape is largely changed even by the application of a small external force. Although the characteristic of softness is suitable for the use of coating or printing means, it is required to carry out some processing from the viewpoint of stability of the shape. Therefore, in the present first embodiment, bonding electrodes 6 are formed by imparting energy to the gold nanopaste in a fed state by coating or printing, or imparting energy, for example, heat, ultrasonic waves, electron heat or the like to promote the positive evaporation of the additive elements 9b and bring a distance between individual gold nanoparticles 9a close to one another or by promoting the combining of the gold nanoparticles 9a to improve the hardness and so on further than in the fed state. For example, by imparting the energy to the gold nanopaste, the nanopaste can be formed into a metal film. The thus-formed bonding electrode 6 has plasticity (i.e., plasticity in a state stabilized further than the gold nanopaste in the state immediately after feed) that its shape can easily be changed by an external force once positively applied while keeping hardness and viscosity to the extent that the shape can be stably maintained so long as no external force is applied and the deformed shape can be maintained by stopping the application of the external force. Therefore, the process with energy impartment can also be regarded as a stabilization process for the gold nanopaste.

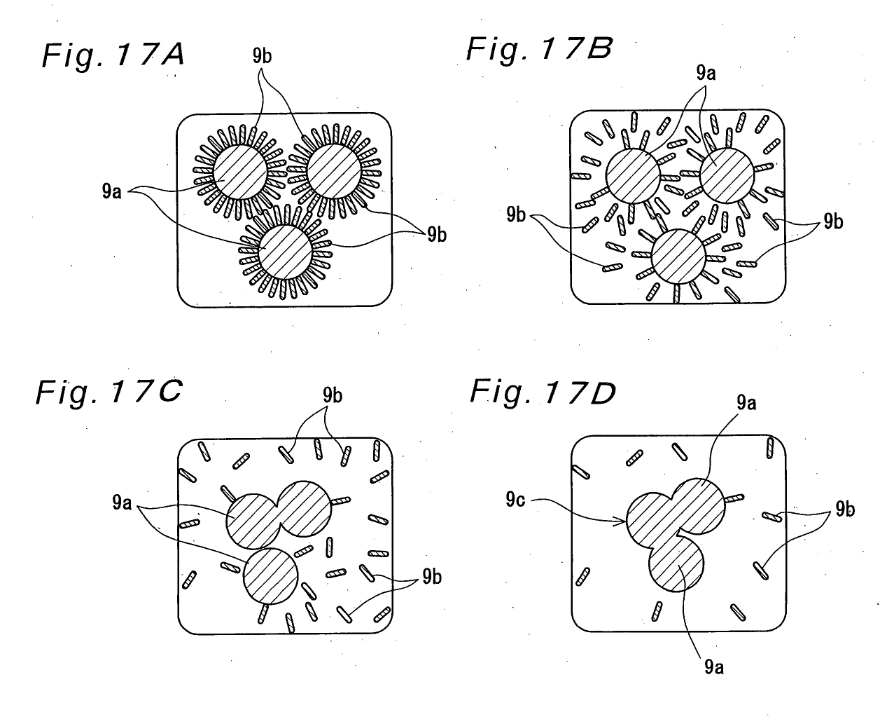

In this case, the mechanism of the stabilization process with energy impartment to the gold nanopaste is herein described in detail with reference to the schematic sectional views shown in FIGS. 17A, 17B, 17C and 17D.

First of all, as shown in FIG. 17A, the gold nanopaste is constituted of numbers of gold nanoparticles 9a and additive elements 9b. The additive elements 9b are provided by, for example, dispersants (hereinafter referred to as dispersants 9b) such that individual gold nanoparticles 9a exist independently without causing mutual fusion. As shown in FIG. 17A, surfaces of the individual gold nanoparticles 9a are put in a state in which they are covered with the dispersants 9b and exist mutually independently. It is to be noted that such gold nanoparticles 9a that independently exist are referred to as independently dispersed nanoparticles.

If the energy of heat, electron beams or the like is applied to the gold nanopaste in the above state, then the dispersants 9b that cover the surfaces of the gold nanoparticles 9a are peeled off from the surfaces of the gold nanoparticles 9a and thereafter gasified and evaporated as shown in FIG. 17B. With the dispersants 9b thus peeled off, the fresh (clean) outer surfaces of the gold nanoparticles 9a are exposed, and consequently, the fusion between the adjacently located gold nanoparticles 9a starts as shown in FIG. 17C.

When the fusion is promoted, the plurality of gold nanoparticles 9a fuse together as shown in FIG. 17D, and gold particles 9c larger than the original gold nanoparticles 9a are formed. As a result, the gold nanopaste, which has had the characteristic of softness, is put into a gold bulk (solid) state. The mechanism of the sequence can be regarded as the sintering mechanism of the gold nanopaste.

In the present first embodiment, the bonding electrodes 6 formed by carrying out the solidification of the gold nanopaste, i.e., the stabilization process are required to be provided with a characteristic that the electrodes can easily be deformed by applying an external force, and the characteristic can be obtained by setting the conditions of the intensity and the duration of impartment of energy at the time of energy impartment.

Moreover, concrete means of coating, printing or the like of the gold nanopaste include a method for feeding the gold nanopaste by means of, for example, a screen and a squeegee and a method for feeding the gold nanopaste by means of an inkjet system or the like. Moreover, dissimilarly to the formation heights of the bumps 5 formed by the plating method, the feed rate of the gold nanopaste can be precisely controlled according to the methods of feeding the gold nanopaste as described above, and therefore, the bonding electrodes 6 can be formed while minutely controlling the formation heights thereof. The formation height (thickness) of each of the bonding electrodes 6 is set to, for example, about 20 μm. Moreover, the bonding electrodes 6 are formed so that the feed rate of the gold nanopaste onto each of the board-electrodes 4 of the board 3 is regulated in consideration of a difference in the tip height position of the bumps 5 formed on the P-pole pads 2p and the N-pole pads 2n of the LED chip 1 and the respective formation heights (thicknesses) are mutually varied. That is, in a state in which the LED chip 1 is arranged above the board 3 approximately parallel to each other (i.e., approximately in a horizontal state) with their pads 2 and the board-electrodes 4 aligned in position as shown in FIG. 4D, the bonding electrodes 6 are formed by determining the respective formation thicknesses according to a difference in the distance between the tips of the bumps 5 and the board-electrodes 4 of the board 3 on the basis of the variation in the tip height position of the bumps 5 of the LED chip 1. That is, in consideration of the fact that the distance between the tip of the bump 5 formed on the P-pole pad 2p and the board-electrode 4 is shorter than the distance between the tip of the bump 5 formed on the N-pole pad 2n and the board-electrode 4, the bonding electrodes 6 are formed so that the formation thickness dimension of the bonding electrode 6 arranged between the bump 5 of the P-pole pad 2p and the board-electrode 4 becomes smaller than the formation thickness dimension of the bonding electrode 6 arranged between the bump 5 of the N-pole pad 2n and the board-electrode 4 by the difference between them. It is to be noted that the stabilization process of the gold nanopaste is not limited only to the energy impartment carried out as described above, and it may be a case where the stabilization process is carried out by, for example, leaving the gold nanopaste for a prescribed time or in a similar manner. This is because the evaporation of the additive elements 9b included in the gold nanopaste can be promoted even in the above case, allowing the gold nanoparticles 9a to be brought closer to each other for an improvement in the conductive property of the bonding electrodes 6. However, it is more appropriate to positively carry out the stabilization process by energy impartment from the viewpoints of a reduction in the mounting time and prompt retainment of the shape formed by coating or printing.

Subsequently, as shown in FIG. 4D, the LED chip 1 and the board 3 are aligned in position. The positioning is carried out so that the pads 2 are aligned in position with the board-electrodes 4 by relatively moving the LED chip 1 and the board 3 in the state in which they are arranged parallel to each other while sucking and holding the held surface 1a (upper surface in the figure) of the surface opposite from the pad formation surface on which the pads 2 of the LED chip 1 are formed by a holding surface 7a of a suction nozzle 7 of one example of the component holding member.

After the positional alignment, as shown in FIG. 4E, the suction nozzle 7 is moved down to bring the tips of the bumps 5 of the LED chip 1 in contact with the respective board-electrodes 4 of the board 3 via the bonding electrodes 6. Since the bonding electrodes 6 are formed so as to have varied thickness dimensions in accordance with the distance dimensions between the tips of the bumps 5 and the board-electrodes 4 at the time of this contact, the tips of the bumps 5 are brought in contact with the respective bonding electrodes 6 approximately concurrently. Therefore, the contact is achieved while the mutually parallel state of the LED chip 1 and the board 3 is maintained. After this contact, the descent of the suction nozzle 7 is stopped, maintaining the contact state. It may be a case where the suction nozzle 7 is further moved down by a very small amount to press (pressurize) the bumps 5 after the contact to minutely deform the bonding electrodes 6 taking advantage of the fact that the bonding electrodes 6 are formed of the gold nanopaste and have the characteristic of softness. In the above case, it is possible to reliably bring the bumps 5 in contact with the respective bonding electrodes 6 with sufficient contact areas secured by minutely deforming the bonding electrodes 6 even when the formation heights of the bumps 5 are different due to errors of the formation accuracy.

Subsequently, as shown in FIG. 4E, the ultrasonic vibrations are applied from the suction nozzle 7 to the LED chip 1 with this contact state maintained. The ultrasonic vibrations are transmitted to the pads 2, the bumps 5, the bonding electrodes 6 and the board-electrodes 4. With the application of the ultrasonic vibrations, the tip surfaces of the bumps 5 and the upper surfaces of the bonding electrodes 6, which are mutually pressurized and brought in contact with each other, are abraded to have fresh surfaces that are not contaminated with organic substances and so on, and the fresh surfaces mutually adhere to enter a metallically bonded state. Moreover, since the bumps 5 and the bonding electrodes 6 are securely brought in contact with each other with sufficient contact areas secured as described above, the metal bonding is achieved approximately concurrently at each of the bumps 5. It is to be noted that the ultrasonic vibrations are applied for a prescribed time from the suction nozzle 7 in order to reliably carry out the metal bonding.

By thus carrying out the metal bonding, the pads 2 of the LED chip 1 are bonded to the respective board-electrodes 4 of the board 3 via the respective bumps 5 and bonding electrodes 6. Subsequently, the suction and holding of the LED chip 1 by the suction nozzle 7 is released, and the suction nozzle 7 is moved up. As a result, the LED chip 1 is mounted on the board 3, completing an LED chip-mounted board 10 of one example of the semiconductor chip-mounted board. As shown in FIG. 4F, it is also possible to form a sealing material 8 to carry out a sealing process by injecting the sealing material of one example of the insulating material between the surface of the LED chip 1 on which the pads 2 are formed and the surface of the board 3 on which the board-electrodes 3 are formed, reliably protecting the bonded portions of the LED chip 1 and the board 3.

Although the gold nanopaste is used as, for example, the conductive material in the paste form according to the above description, the present first embodiment is not limited only to the case. For example, it may be a case where a silver (Ag) nanopaste is used instead of the above case. The silver nanopaste has an advantage that it is less expensive than the gold nanopaste. However, the silver nanopaste has a feature that it tends to be oxidized in comparison with the gold nanopaste and easily cause migration. Therefore, it is desirable to use the gold nanopaste in a case where more stable, reliable and highly accurate bonding is demanded.

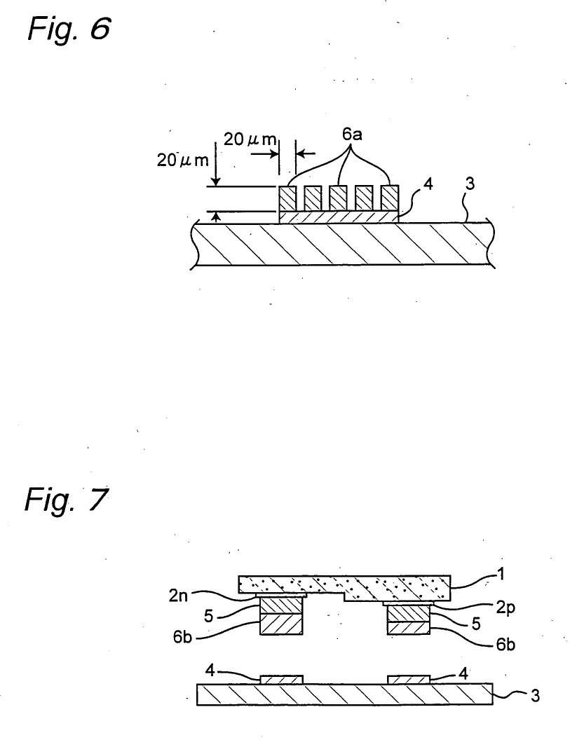

Moreover, although the one bonding electrode 6 is formed on the upper surface of each board-electrode 4 according to the above description, the present first embodiment is not limited only to the case. Instead of the above case, for example, it may be a case where a plurality of bonding electrodes 6a are formed so that a plurality of protrusions are formed on the upper surface of one board-electrode 4 as shown in, for example, the schematic enlarged sectional view of the board-electrode 4 in FIG. 6. In the above case, the formation width can be made smaller than the formation height of each bonding electrode 6a, and therefore, each bonding electrode 6a is allowed to have a shape (aspect ratio) that is more easily deformed by the application of the ultrasonic vibrations. Therefore, the time required for the bonding by the application of the ultrasonic vibrations can be shortened, and more reliable and stable bonding can be achieved by virtue of the provision of the shape that is easy to deform. It is to be noted that the bonding electrodes 6a can be formed of the gold nanopaste by, for example, printing by means of the inkjet system or the like. Moreover, the individual bonding electrodes 6a are formed to have a formation width of about 20 μm and a formation height of about 20 μm. It is desirable that the formation interval (formation pitch) of the bonding electrodes 6 is set to an optimum value according to the bonding state and so on.

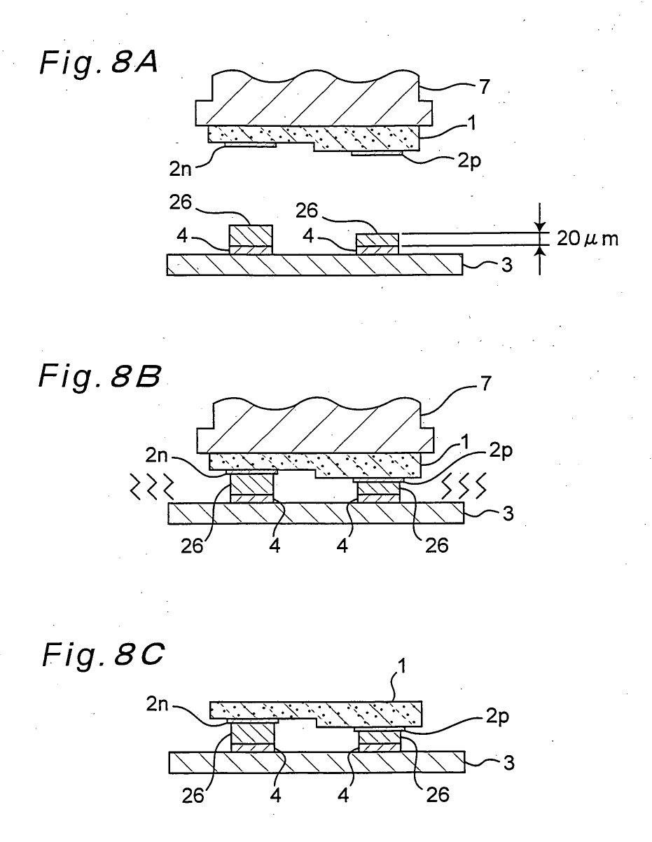

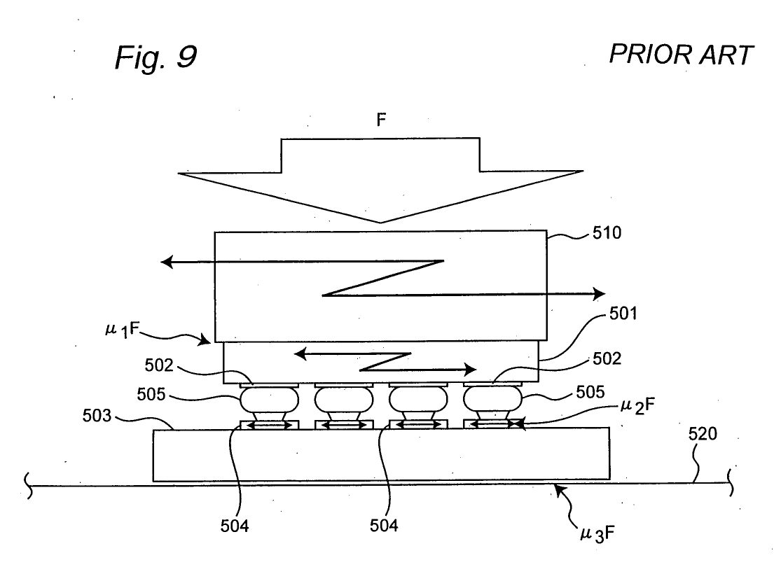

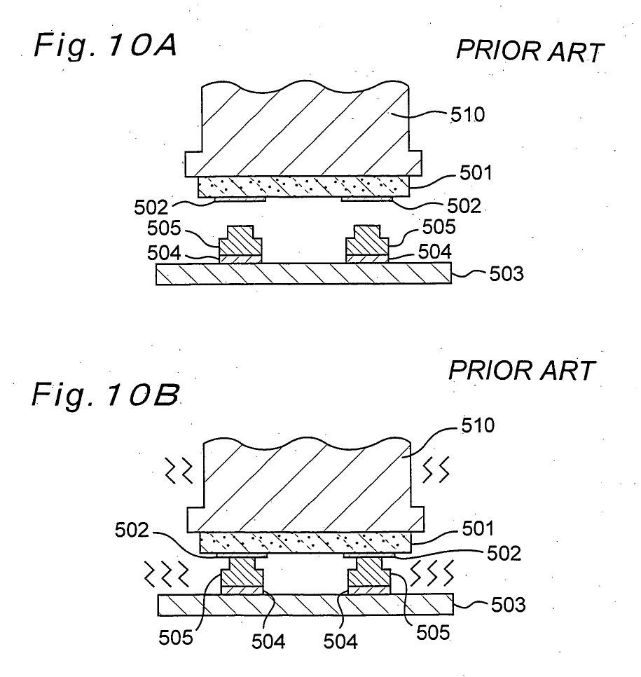

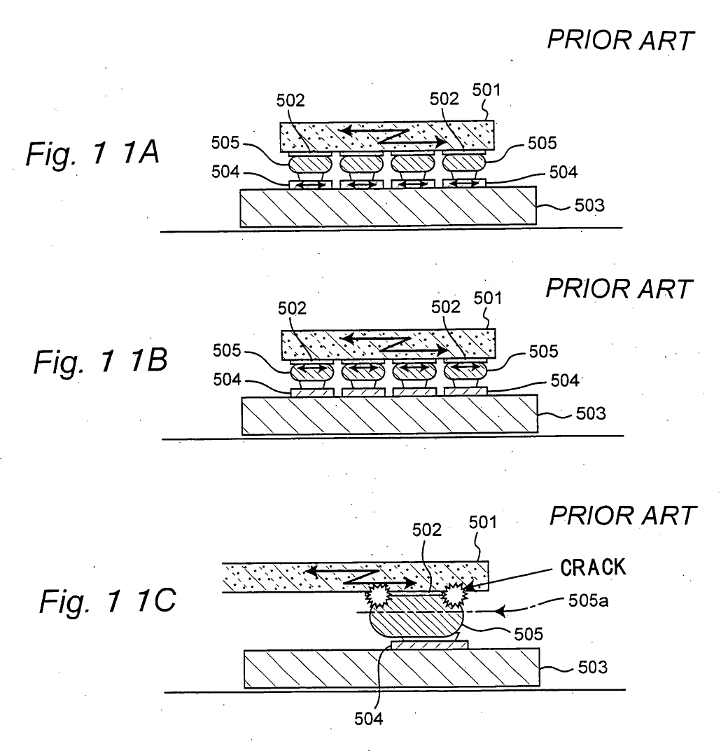

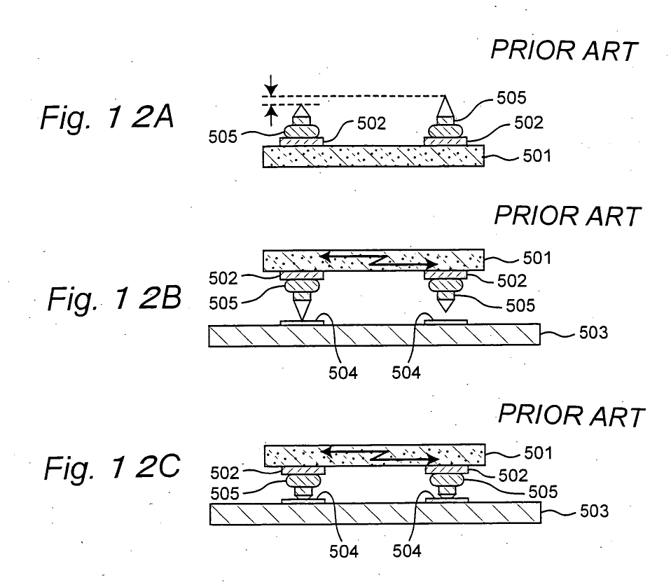

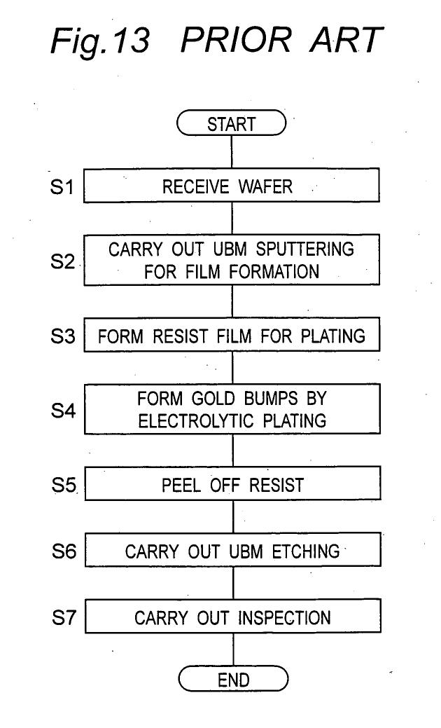

Moreover, the bonding electrodes 6 are formed on the upper surfaces of the board-electrodes 4 of the board 3 according to the above description, the present first embodiment is not limited only to the case. Instead of the above case, for example, it may be a case where the bonding electrodes 6b are formed on the bumps 5 of the LED chip 1 as shown in FIG. 7. This is because the pads 2 can also be brought in contact with the respective board-electrodes 4 via the respective bumps 5 and bonding electrodes 6b even in the above case.

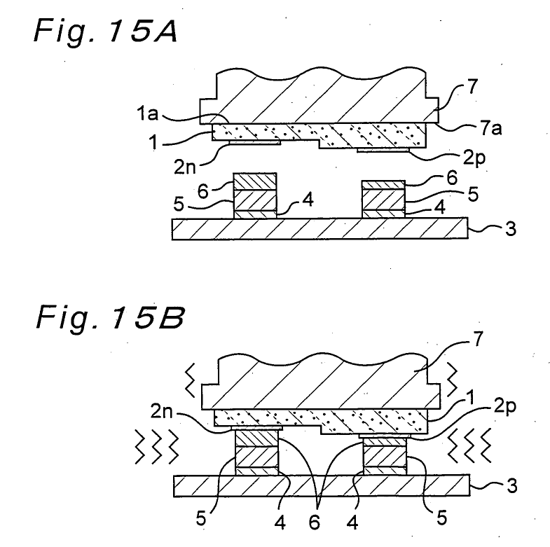

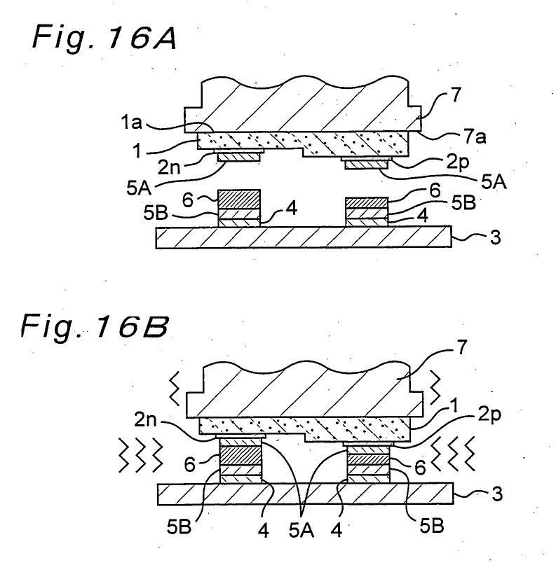

Moreover, for example, it may be a case where the bumps 5 are formed on the board-electrodes 4 of the board 3 and the bonding is achieved by the application of the ultrasonic vibrations as shown in FIGS. 15A and 15B instead of the case where the bumps 5 formed by the plating method are formed on the pads 2 of the LED chip 1. Since the formation heights of the board-electrodes 4 are made approximately uniform on the board 3 with respect to the LED chip 1 of which the formation heights of the pads 2 are different, there is an advantage that the bumps can be formed more efficiently than by the plating method. Further, it may be a case where the bumps 5A and 5B are formed respectively on the pads 2 of the LED chip 1 and the board-electrodes 4 of the board 3, respectively, as shown in FIGS. 16A and 16B.

The following various effects can be obtained according to the first embodiment.

First, the bumps 5 formed on the pads 2 of the LED chip 1 have a high hardness of about 80 to 90 HV, and the board-electrodes 4 of the board 3 have a high hardness of about 70 to 90 HV. Therefore, deforming of the bumps hardly occurs merely by applying the ultrasonic vibrations with both the members brought in contact with each other, it is difficult to achieve sufficient metal bonding. In contrast to this, by arranging the bonding electrodes 6 formed of a metal film produced by imparting energy to the gold nanopaste of the soft conductive material in the paste form between the bumps 5 and the board-electrodes 4 and applying the ultrasonic vibrations with the bumps 5 brought in contact with the respective board-electrodes 4 with interposition of the respective bonding electrodes 6 that have a hardness sufficiently lower than the aforementioned hardness, sufficient metal bonding can be achieved.

That is, by minutely deforming the bonding electrodes 6 that are softer than the bumps 5 between the bumps 5 and the board-electrodes 4 at the time of the contact, the bumps 5 and the respective board-electrodes 4 can be reliably brought in contact with each other with interposition of the respective bonding electrodes 6. Moreover, a sufficient bonding area (contact area) is secured at the contact portions of the bumps 5 and the bonding electrodes 6 at the time of this contact. By applying the ultrasonic vibrations in the above state, the metal bonding can reliably be achieved with the sufficient contact area and a sufficient bonding strength, and stable bonding can be achieved. Moreover, since the bonding electrodes 6 formed of the same material are interposed between the bumps 5 and the board-electrodes 4, the bonding conditions of the bumps 5 and the board-electrodes 4 can be made similar to each other. Therefore, the bonding between the bumps 5 and the board-electrodes 4 with interposition of the bonding electrodes 6 can be concurrently achieved. Therefore, this allows the prevention of the problem of the occurrence of stress concentration due to the preceding bonding of some bumps and so on and allows the bonding to be achieved with higher accuracy and stability.

Moreover, the bumps 5 formed by the plating method sometimes have varied formation heights depending on the formation accuracy. Even when there is variation in the formation height, the bumps 5 can reliably be brought in contact with the respective board-electrodes 4 with interposition of the respective bonding electrodes 6 while absorbing the variation in the formation height of the bumps 5 by the bonding electrodes 6 by virtue of the bonding electrodes 6 formed of the gold nanopaste of the soft material, and reliable and stable bonding can be achieved by the application of the ultrasonic vibrations.

Moreover, by carrying out the stabilization process by imparting energy to the gold nanopaste that has the characteristic of excessive softness for the retainment of the shape after the feed by coating or printing, the shape can be stably retained, and reliable contact and bonding can be achieved. Particularly, the stabilization process can be carried out by imparting energy of heat, ultrasonic waves, electron beams or the like without using a special chemical solution or the like, and therefore, prompt and reliable processing can be achieved.

Moreover, by applying the ultrasonic vibrations in the state in which the bumps 5 are reliably brought in contact with the respective board-electrodes 4 with interposition of the respective bonding electrodes 6, the tips of the bumps 5 and the respective bonding electrodes 6 can be approximately concurrently bonded together, and the time required for the bonding can be shortened. Therefore, the occurrence of the problem of defective bonding due to the event that the bonding is not approximately concurrently achieved or the time required for the bonding becomes long can be prevented in advance.

Moreover, the bonding electrodes 6 formed of the gold nanopaste to which the energy has been imparted have the characteristic of softness of a hardness significantly lower than that of the bumps 5. Therefore, the stress concentration due to the application of the ultrasonic vibrations to the bumps 5 of the high hardness does not occur, and the occurrence of the problem that cracks are generated in the bumps 5 can be reduced.

Moreover, by forming the bonding electrodes 6 so that the thickness dimensions are different by regulating the feed rate of the gold nanopaste according to the difference in the distance dimension between the tips of the bumps 5 formed on the LED chip 1 having the feature that the formation heights of the P-pole pad 2p and the N-pole pad 2n differ from each other and the respective board-electrodes 4 of the board 3, reliable and stable mounting can be carried out coping with the difference in the formation height between the P-pole pad 2p and the N-pole pad 2n. That is, even when the formation heights of the pads 2 are different as described above, the mounting of the LED chip can be carried out by adjusting the difference with the bonding electrodes 6 while keeping the levelness between the LED chip 1 and the board 3.

Moreover, since the bonding electrodes 6 can be formed by minutely controlling the feed rate of the gold nanopaste by means of coating, printing or the like taking advantage of the characteristic that the electrodes is made of the soft material in the paste form, the control of the thickness dimension can reliably be achieved.

As described above, by virtue of the ultrasonic bonding (metal bonding) allowed to be achieved by using the gold nanopaste, the LED chip 1, which has the features that it has an allowable temperature of not higher than about 200° C. being lower than the solder melting point of 238° C. and is susceptible to heat, can be mounted on the board 3 without using reflow soldering. With this arrangement, the occurrence of damages exerted on the LED chip due to heat and generated gas during the conventional reflow soldering can be prevented in advance. Moreover, a flux feed process and a cleaning process, which has been required due to the use of solder, can be eliminated to reduce the time and labor, allowing efficient mounting to be achieved. In addition, this can cope with the recent environmental problems.

Therefore, according to the mounting method of the first embodiment, the mutual bonding of the pads 2, the bumps 5 and the board-electrodes 4, which are formed in a large size for letting heat generated in accordance with the voltage application to the LED chip 1 toward the board 3 side can be carried out reliably and efficiently by virtue of the use of the bonding electrodes 6 while effectively imparting sufficient ultrasonic vibrations and shortening the vibration applying time.

### Second Embodiment

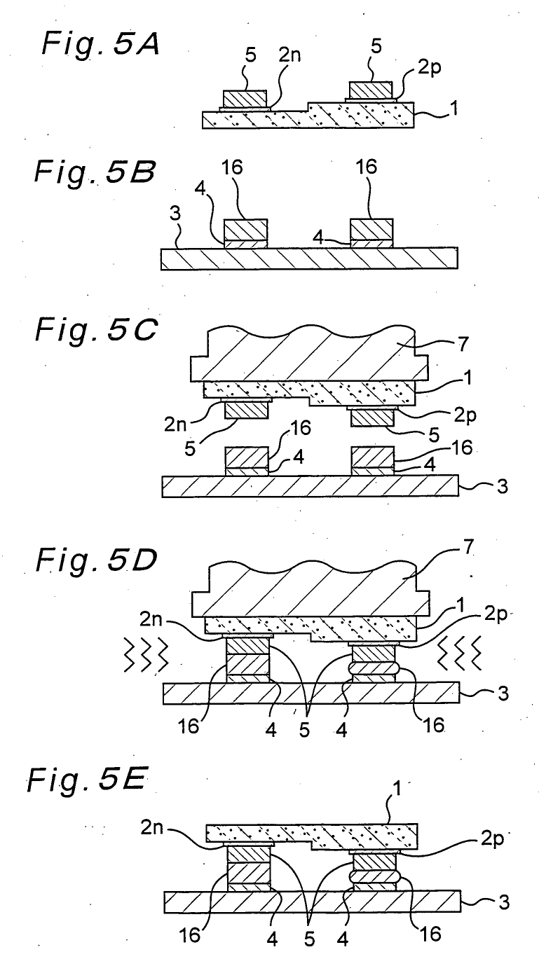

The present invention is not limited to the above embodiment but allowed to be implemented in various forms. For example, a mounting method of the LED chip 1 of one example of the semiconductor chip mounting method according to a second embodiment of the present invention will be described with reference to the schematic explanatory views shown in FIG. 5. The same constituents as those owned by the LED chip 1 and the board 3 of the first embodiment are denoted by the same reference numerals for the purpose of easily understanding the explanation.

First, as shown in FIG. 5A, the bumps 5 are formed on the respective pads 2 on the upper surface of the LED chip 1 similarly to the first embodiment. The bumps 5 are formed of, for example, gold by the plating method. Moreover, since there is a difference in the formation height (e.g., a difference in the formation height of 2 μm) between the P-pole pad 2p and the N-pole pad 2n of the LED chip 1, a height difference of the same degree exists also in the height positions of the tips of the formed bumps 5.

Moreover, as shown in FIG. 5B, a gold nanopaste is fed onto the illustrated upper surface of the board-electrodes 4 of the board 3 by the coating or printing means to form the bonding electrodes 16. The thus-formed bonding electrodes 16 are formed in a formation thickness of about 20 μm with the formation thickness made approximately uniform, dissimilarly to the case of the first embodiment. Moreover, by imparting prescribed energy to the gold nanopaste fed as described above, the bonding electrodes 16 are formed with stabilized shapes.

Subsequently, as shown in FIG. 5C, the surface of the LED chip 1 on the side where the pads 2 are not formed is sucked and held by the suction nozzle 7 to place the chip above the board 3, and the pads 2 of the LED chip 1 and the board-electrodes 4 of the board 3 are mutually bondably aligned in position in a direction along the surface of the board 3.

After the positional alignment, the suction nozzle 7 is moved down to lower the LED chip 1 so as to bring the tips of the bumps 5 of the LED chip 1 in contact with the respective bonding electrodes 16. At this time, the height positions of the tips of the bumps 5 are mutually varied as described above, and therefore, the bump 5 formed on the P-pole pad 2p is brought in contact with the bonding electrode 16 ahead of the bump 5 formed on the N-pole pad 2n. After this contact, the suction nozzle 7 is further moved down minutely continuously, so that the bonding electrode 16 put in the contact state is deformed by being pressurized against the bump 5 formed on the P-pole pad 2p. By thus deforming the bonding electrode 16, the bump 5 formed on the N-pole pad 2n that is not put in the contact state can be further lowered, and the bump 5 can be brought in contact with the bonding electrode 16 as shown in FIG. 5D. While maintaining this contact state, i.e., the state in which the bonding electrodes 16 are pressurized by being brought in contact with the bumps 5, the descent operation of the suction nozzle 7 is stopped.

Subsequently, as shown in FIG. 5D, the ultrasonic vibrations are applied for a prescribed time from the suction nozzle 7 to the LED chip 1 with this contact state maintained. By the application of the ultrasonic vibrations, the tip surfaces of the bumps 5 and the upper surfaces of the bonding electrodes 16, which are pressurized against and brought in contact with each other, mutually adhere and enter the metal bonded state.

By thus carrying out the metal bonding, the pads 2 of the LED chip 1 are bonded to the respective board-electrodes 4 of the board 3 via the respective bumps 5 and bonding electrodes 16. Subsequently, the suction and holding of the LED chip 1 by the suction nozzle 7 is released, and the suction nozzle 7 is moved up. As a result, the LED chip 1 is mounted on the board 3 as shown in FIG. 5E.

According to the second embodiment, even when the bonding electrodes 6 are formed with the formation heights unvaried according to the difference in the tip height position of the bumps 5 attributed to the difference in the formation height between the P-pole pad 2p and the N-pole pad 2n of the LED chip 1 as in the first embodiment, the difference in the tip height position of the bumps 5 can be absorbed by deforming the bonding electrodes 16 with a pressure from the bumps 5 according to the formation heights of the bumps 5 taking advantage of the characteristic that the bonding electrodes 16 are formed of the gold nanopaste that is the conductive material in the paste form and soft (softer than the bumps 5 and so on).

Therefore, even when there are differences in the formation height of the pads 2 and the formation height of the bumps 5 as described above, reliable contact can be achieved by deforming the bonding electrodes 16. Moreover, by applying the ultrasonic vibrations in the secure contact state as described above, the bumps 5 and the bonding electrodes 16 can reliably be metallically bonded, and the mounting of the LED chip 1 on the board 3 can reliably be achieved by the application of the ultrasonic vibrations.

Moreover, the mounting method described above can be applied not only to the case where it is previously understood that the formation heights of the P-pole pad 2p and the N-pole pad 2n are mutually varied as in the case of the LED chip 1 but also to a case where the formation heights of the pads and bumps are varied due to the formation accuracy, and the method can be regarded as a mounting method of higher versatility.

### Third Embodiment

A mounting method of the LED chip 1 of one example of the semiconductor chip mounting method according to a third embodiment of the present invention will be described with reference to the schematic explanatory views shown in FIGS. 8A, 8B and 8C. The same constituents as those owned by the LED chip 1 and the board 3 of the first embodiment are denoted by the same reference numerals for the purpose of easily understanding the explanation.

According to the third embodiment of the present invention, mounting is carried out without forming bumps instead of forming bumps on the pads 2 of the LED chip 1 by the plating method and mounting the LED chip 1 on the board 3 with interposition of the bumps as in the first embodiment and the second embodiment.

First of all, as shown in FIG. 8A, bonding electrodes 26 are formed by feeding a gold nanopaste onto the upper surfaces of the board-electrodes 4 of the board 3 by coating or printing means. At this time, the bonding electrodes 26 are formed while minutely regulating the feed rate of the gold nanopaste so that the thickness dimensions of the bonding electrodes 26 are varied in accordance with the formation heights of the P-pole pad 2p and the N-pole pad 2n of the LED chip 1 similarly to the mounting method of the first embodiment. In forming the-bonding electrodes 26, the formed shape is stabilized by imparting prescribed energy to the fed gold nanopaste.

Subsequently, as shown in FIG. 8A, the surface of the LED chip 1 on the side where the pads 2 are not formed is sucked and held by the suction nozzle 7 to place the chip above the board 3, and the pads 2 of the LED chip 1 and the board-electrodes 4 of the board 3 are mutually bondably aligned in position in a direction along the surface of the board 3.

After the positional alignment, the suction nozzle 7 is moved down to lower the LED chip 1 so as to bring the pads 2 of the LED chip 1 in contact with, the respective bonding electrodes 26. At this time, although the height positions of the pads 2 of the LED chip 1 are different, the bonding electrodes 26 are formed on the board 3 in conformity to the variation. Therefore, the contact of the P-pole pad 2p with the bonding electrode 26 and the contact of the N-pole pad 2n with the bonding electrode 26 are approximately concurrently achieved. The descent operation of the suction nozzle 7 is stopped with this contact state maintained. In this state, the state in which the bonding electrodes 26 are brought in contact with and pressurized against the respective pads 2 is maintained.

Subsequently, as shown in FIG. 8B, the ultrasonic vibrations are applied for a prescribed time from the suction nozzle 7 to the LED chip 1 with this contact state maintained. By the application of the ultrasonic vibrations, the surfaces of the pads 2 and the upper surfaces of the bonding electrodes 26, which are mutually pressurized and brought in contact with each other, mutually adhere and enter the metal bonded state.

By thus carrying out the metal bonding, the pads 2 of the LED chip 1 are bonded to the respective board-electrodes 4 of the board 3 via the respective bonding electrodes 26. Subsequently, the suction and holding of the LED chip 1 by the suction nozzle 7 is released, and the suction nozzle 7 is moved up. As a result, the LED chip 1 is mounted on the board 3 as shown in FIG. 8C.

Although the bonding electrodes 26 are formed on the respective board-electrodes 4 of the board 3 according to the above description, it may be a case where the bonding electrodes 26 are formed on the pads 2 of the LED chip 1 instead of the above case. This is because the pads 2 and the respective board-electrodes 4 can be brought in contact with each other with interposition of the respective bonding electrodes 26 in either case.

According to the third embodiment, the pads 2 and the, respective board-electrodes 4 can be bonded together with interposition of the bonding electrodes 26 by applying the ultrasonic vibrations in the state in which the pads 2 and the respective board-electrodes 4 are brought in contact with each other with interposition of the respective bonding electrodes 26 instead of forming bumps dissimilarly to the mounting methods of the first embodiment and the second embodiment by which the bumps 5 are formed by the plating method or the like on the pads 2 of the LED chip 1 or the board-electrodes 4 of the board 3.

According to the mounting method described above, the bump forming process by the plating method is not carried out. Therefore, time and labor required for the process can be eliminated, and a more efficient mounting method can be provided.

In this case, generic conditions required for the bonding (the ultrasonic bonding) when the ultrasonic vibrations are applied in each of the aforementioned embodiments will be described with reference to the schematic explanatory view of FIG. 9 that shows the conventional ultrasonic bonding method.

According to the conventional ultrasonic bonding method shown in FIG. 9, in a state in which bumps 505 formed on chip-electrodes 502 of a semiconductor chip 510 sucked and held by a suction nozzle 510 are brought in contact with board-electrodes 504 of a board 503 while being pressurized with a bonding load F of a prescribed vertical load, the ultrasonic vibrations are applied from the suction nozzle 510 to carry out the ultrasonic bonding. At this time, it is assumed that a friction coefficient between the surface of the suction nozzle 510 for holding the semiconductor chip 510 and the illustrated upper surface of the semiconductor chip 501 is μ1, a friction coefficient between the bumps 505 and the board-electrodes 504 that are put in a mutual contact state is μ2, and a friction coefficient between the board 503 and a stage 520 by which the board 503 is held is μ3.

With regard to the above ultrasonic bonding, it is preferable to secure the condition of (μ3F>μ1F>μ2F) in order to carry out ideal ultrasonic bonding. That is, it is preferable that the ultrasonic vibrations are effectively transmitted to the contact portions of the bumps 505 and the board-electrodes 504 by applying the ultrasonic vibrations by the suction nozzle 510, and it is not preferable that the ultrasonic vibrations are positively transmitted to an interface between the holding surface of the suction nozzle 510 and the semiconductor chip 501 and an interface between the board 3 and the stage 520. For example, on the condition of (μ2F>μ1F), the ultrasonic vibrations are more positively transmitted to the interface between the holding surface of the suction nozzle 510 and the semiconductor chip 501 than to the contact portions of the bumps 505 and the board-electrodes 504. In the above case, a sideslip occurs between the suction nozzle 510 and the semiconductor chip 501, possibly causing a case where the ultrasonic bonding itself cannot be carried out.

In contrast to this, according to the mounting method of the aforementioned embodiments of the present invention, the application of the ultrasonic vibrations is carried out in the state in which the bonding electrodes formed of the gold nanopaste that has undergone prescribed energy impartment and the stabilization process are interposed between the pads 2 of the LED chip 1 and the respective board-electrodes 4 of the board 3. Therefore, the ultrasonic vibrations can be positively concentrated on the bonding electrodes that are the softest portions. Therefore, more effective bonding by which the time required for the ultrasonic bonding is shortened can be achieved. Therefore, a bonding method by the application of ultrasonic vibrations capable of preventing in advance the sideslip of the suction nozzle and damages of the LED chip, the bumps and so on can be provided.

Moreover, the gold nanopaste is fed onto the pads 2 of the LED chip 1, the bumps 5 and the board-electrodes 4 of the board 3 and the bonding electrodes are formed in the required positions according to the description of the aforementioned embodiments, the present invention is not limited only to the case. Instead of the case, for example, it may be a case where a sheet such that bonding electrodes formed of gold nanopaste are arranged in an insulation sheet is preparatorily formed of the gold nanopaste and the insulating material, the bonding electrodes formed in the sheet are aligned in position with the pads 2 of the LED chip 1 and the board-electrodes 4 of the board 3, and thereafter, the pads 2 of the LED chip 1 and the board-electrodes 4 of the board 3 are brought in contact with each other with interposition of the bonding electrodes in the sheet. By applying the ultrasonic vibrations in the contact state, the pads 2 and the board-electrodes 4 can be bonded together with interposition of the bonding electrodes in the sheet. Moreover, a sealing process for sealing the peripheries of the bonded portions with the insulating material in the sheet can be carried out concurrently with it.

Moreover, although the case where the semiconductor chip is the LED chip 1 has been mainly described in connection with the aforementioned embodiments, the semiconductor chip is not limited only to the case. It is needless to say that the mounting method of the present invention can be applied regardless of the functions and so on 6f the semiconductor chip so long as the semiconductor chip is mounted on a board via chip-electrodes. Moreover, the mounting method of the present invention can be applied to a case where a plurality of chip-electrodes are formed on such a semiconductor chip or a case where only one chip-electrode is formed.

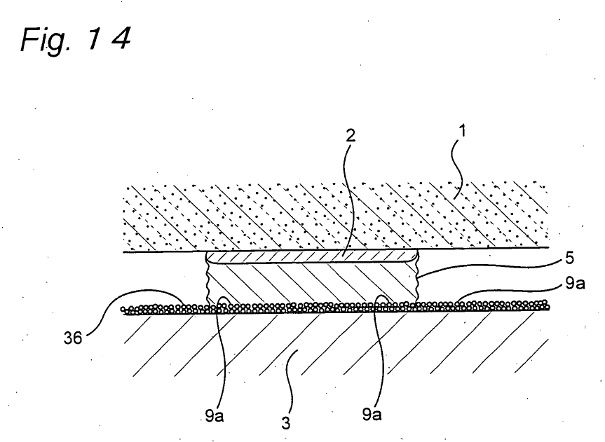

Moreover, as one example of the actual mounting state of the LED chip on the board, FIG. 14 shows an enlarged sectional view of the bonded portion in the state in which the LED chip 1 is mounted on the board 3. As shown in FIG. 14, the bump 5 is formed on the pad 2 of the LED chip 1, and an electrode wiring 36 formed of a gold nanopaste is formed on the board 3. The mounting is carried out by applying the ultrasonic vibrations in a state in which the lower tip of the bump 5 is brought in contact with the electrode wiring, as a consequence of which the surface of the lower tip of the bump 5 and the surface of the electrode wiring 36 brought in contact with the surface are metallically bonded together. It is to be noted that the bump 5 is formed in a size of 50 μm×50 μm.

Moreover, the ultrasonic bonding is carried out by applying the ultrasonic vibrations to the bonding electrodes 6 formed of the gold nanopaste according to the description of the aforementioned embodiments, the bonding method using such a bonding electrode 6 is not limited only to the case. Instead of the above case, it may be a case where the bonding is carried out by pressurizing the bonding electrodes 6 interposed between the respective pads 2 and board-electrodes 4 without the application of the ultrasonic vibrations to deform the shape and bringing the pads 2 in contact with the respective board-electrodes 4 with interposition of the respective bonding electrodes 6. It may be a case where the bonding electrodes 6 are heated after the contact and thereafter cooled and hardened or a case where the bonding is carried out by naturally hardening the bonding electrodes 6 by leaving the electrodes.

It is to be noted that, by properly combining the arbitrary embodiments of the aforementioned various embodiments, the effects possessed by them can be produced.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

The entire disclosure of Japanese Patent Application No. 2003-347977 filed on Oct. 7, 2003, including specification, drawings and claims are incorporated herein by reference in its entirety.

1. A semiconductor chip mounting method for mounting a semiconductor chip that has a chip-electrode bondable to a board-electrode of a board by bonding the chip-electrode to the board-electrode, the method comprising:
arranging a bonding member formed of a conductive material in paste form between the chip-electrode and the board-electrode and bringing the chip-electrode in contact with the board-electrode by interposing the bonding member; and
applying ultrasonic vibrations to the bonding member and either the chip-electrode or the board-electrode in the contact state, thereby the bonding member is bonded to the board-electrode and the chip-electrode.

2. A semiconductor chip mounting method for mounting a semiconductor chip that has a plurality of chip-electrodes bondable to board-electrodes of a board by bonding the chip-electrodes to the board-electrodes, the method comprising:
arranging bonding members formed of a conductive material in paste form between the chip-electrodes and the board-electrodes and bringing the chip-electrodes in contact with the respective board-electrodes by interposing the bonding members; and
applying ultrasonic vibrations to the bonding members and either the chip-electrodes or the board-electrodes in the contact state, thereby the bonding members are bonded to the board-electrodes and the chip-electrodes.

3. The semiconductor chip mounting method as defined in claim 2, wherein
the conductive material in the paste form is fed by coating or printing to the board-electrodes or the chip-electrodes,
the bonding members are formed by imparting energy to the fed conductive material in the paste form, and
then, the chip-electrodes are brought in contact with the respective board-electrodes with interposition of the bonding members.

4. The semiconductor chip mounting method as defined in claim 3, wherein the bonding members are formed by stabilizing shapes thereof formed of the conductive material in the paste form with imparting the energy thereto, after the conductive material in the paste form is fed.

5. The semiconductor chip mounting method as defined in claim 3, wherein the conductive material in the paste form is a gold nanopaste, and the bonding material is a metal film produced by imparting the energy to the gold nanopaste.

6. The semiconductor chip mounting method as defined in claim 3, wherein the chip-electrodes are brought in contact with the respective board-electrodes with interposition of the bonding members by deforming the bonding members with pressurizing the chip-electrodes against the board-electrodes with interposition of the bonding members.

7. The semiconductor chip mounting method as defined in claim 3, wherein a plurality of the bonding members are formed on the individual board-electrodes or the individual chip-electrodes.

8. The semiconductor chip mounting method as defined in claim 3, wherein the ultrasonic vibrations are applied to the bonding members through the semiconductor chip by a component holding member in a state in which a surface to be held opposite from a surface of the semiconductor chip on which the chip-electrodes are formed is held by a holding surface of the component holding member.

9. The semiconductor chip mounting method as defined in claim 3, wherein the semiconductor chip has a P-type electrode and an N-type electrode, whose thickness dimensions are different from each other, as the chip-electrodes, and
the bonding members are formed so that the thickness dimensions of the bonding members are varied in accordance with a difference in a distance dimension between the chip-electrodes and the board-electrodes depending on the difference in the thickness dimension between the P-type electrode and the N-type electrode.

10. The semiconductor chip mounting method as defined in claim 2, wherein
the semiconductor chip has a plurality of protruding electrodes formed on the chip-electrodes,
the bonding members are formed by feeding the conductive material in the paste form to the protruding electrodes or the board-electrodes and imparting energy to the conductive material in the paste form, and
the chip-electrodes are brought in contact with the respective board-electrodes by interposition of the bonding members and the protruding electrodes.

11. The semiconductor chip mounting method as defined in claim 10, wherein the protruding electrodes are formed of a conductive material by a plating method.

12. The semiconductor chip mounting method as defined in claim 10, wherein
the semiconductor chip has a P-pole electrode and an N-pole electrode, whose thickness dimensions are different from each other, as the chip-electrodes, and
the bonding members are fed so that thickness dimensions of the bonding members are varied in accordance with a difference in a distance dimension between tips of the protruding electrodes and the board-electrodes caused by a difference in a tip height position of the protruding electrodes based on the difference in the thickness dimension of the chip-electrodes.

13. The semiconductor chip mounting method as defined in claim 2, wherein
the board has a plurality of protruding electrodes formed on the board-electrodes,
the bonding members are formed by feeding the conductive material in the paste form to the protruding electrodes or the chip-electrodes and imparting energy to the conductive material in the paste form, and
the chip-electrodes are brought in contact with the respective board-electrodes with interposition of the bonding members and the protruding electrodes.

14. The semiconductor chip mounting method as defined in claim 13, wherein
the semiconductor chip has a P-pole electrode and an N-pole electrode, whose thickness dimensions are different from each other, as the chip-electrodes,
the bonding members are fed so that thickness dimensions of the bonding members are varied in accordance with a difference in a distance dimension between the chip-electrodes and the tips of the protruding electrodes caused by a difference in a thickness dimension of the chip-electrodes.

15. The semiconductor chip mounting method as defined in claim 3, wherein the board-electrodes of the board are subjected to a plasma cleaning process before the contact between the chip-electrodes of the semiconductor chip and the board-electrodes of the board with interposition of the bonding members.

16. The semiconductor chip mounting method as defined in claim 3, wherein, after the bonding between the chip-electrodes of the semiconductor chip and the board-electrodes of the board with interposition of the bonding members, peripheries of the bonded portions are subjected to a sealing process with an insulating material.

17. The semiconductor chip mounting method as defined in claim 3, wherein the semiconductor chip is an LED chip, and the bonding members have a function to transfer heat generated by voltage application to the LED chip toward the board side.

18. A semiconductor chip-mounted board comprising:
a board having a plurality of board-electrodes;
a semiconductor chip having a plurality of chip-electrodes electrically bondable to the board-electrodes; and
a plurality of bonding members that are arranged between the board-electrodes and the chip-electrodes and formed into a metal film by imparting energy to a gold nanopaste,
wherein the semiconductor chip being mounted on the board by bonding the chip-electrodes to the respective board-electrodes with interposition of the bonding members by adhesion of the bonding members to the board-electrodes or the chip-electrodes.

19. A semiconductor chip mounting method for mounting a semiconductor chip that has a plurality of chip-electrodes on a board that has a plurality of board-electrodes, the method comprising:
arranging bonding members formed by imparting energy to a conductive material in paste form between the chip-electrodes and the board-electrodes; pressurizing the chip-electrodes against the respective board-electrodes with interposition of the bonding members between the chip-electrodes and the board-electrodes; and deforming the bonding members, thereby bringing the chip-electrodes in contact with the respective board-electrodes with interposition of the bonding members.
